(19) United States
(12) Patent Application Publication
(10) Pub. No.: US 2010/0025837 A1
(43) Pub. Date: Feb. 4, 2010

(54) COMPOSITE SEMICONDUCTOR DEVICE, SEMICONDUCTOR PACKAGE AND SPACER SHEET USED IN THE SAME, AND METHOD FOR MANUFACTURING COMPOSITE SEMICONDUCTOR DEVICE

(75) Inventors: Tomonori Shinoda, Saitama (JP); Hironori Shizuhata, Tokyo (JP); Hirofumi Shinoda, Kanagawa (JP); Yuji Kawamata, Tokyo (JP); Takeshi Tashima, Tokyo (JP); Masato Shimamura, Tokyo (JP); Masako Watanabe, Oita (JP); Masazumi Amagai, Ibaraki (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: LINTEC CORPORATION, Itabashi-ku. TOKYO (JP)

(21) Appl. No.: 12/446,827

(22) PCT Filed: Oct. 22, 2007
(86) PCT No.: PCT/JP2007/070563

§ 371 Date: May 19, 2009

(30) Foreign Application Priority Data
Oct. 24, 2006 (JP) 2006-289070

(51) Int. Cl. H01L 25/065; H01L 23/522; H01L 21/70

(52) U.S. Cl. 257/686; 257/784; 438/109; 257/E25.013; 257/E23.142; 257/E23.01; 257/E21.532

(57) ABSTRACT

The present invention relates to a complex type semiconductor device formed by laminating plural semiconductor packages, wherein it comprises:
an upper semiconductor package which comprises a substrate for wiring and connecting provided with electrodes for conducting packages on a lower surface in the upper semiconductor package and a principal part of the upper semiconductor package disposed on an upper surface and/or a lower surface of the above substrate and which constitutes a relatively upper part,
a lower semiconductor package which comprises a substrate for wiring and connecting provided with electrodes for conducting packages on an upper surface in the lower semiconductor package and a principal part of the lower semiconductor package disposed on an upper surface and/or a lower surface of the above substrate and which constitutes a relatively lower part,
a spacer sheet which comprises a space part corresponding to the principal part of the upper semiconductor package and/or the principal part of the lower semiconductor package disposed between the adjacent upper and lower substrates and through holes disposed in a periphery of the above space part and allowing the electrodes oppositely disposed between the substrates to be communicated with each other and which is adhered onto the above substrates and inserted therebetween,
connection terminals which are provided in an inside of the through holes in the spacer sheet and which are used for conducting the substrates and
connection terminals for external connection which are formed on a lower surface of a substrate for wiring and connecting in a semiconductor package located in a lowermost part and to a production process for the same. The present invention provides a wiring and connecting method by a spacer sheet which ensures an installation space between an upper semiconductor package and a lower semiconductor package in a POP type semiconductor package and prevents short circuit between adjacent connection terminals and which can certainly wire and connect both semiconductor packages, and a complex type semiconductor device of a POP type having a high packaging density prepared is provided by the above method.

### BACKGROUND OF THE INVENTION

The present invention relates to a semiconductor package prepared by using a spacer sheet which certainly wires and connects an upper semiconductor package with a lower semiconductor package without causing short circuit in a complex type semiconductor device of a POP (package-on-package) type comprising combination of plural semiconductor packages to ensure an installation space between both semiconductor packages and which is provided between both semiconductor packages and a production process for the same.

### RELATED ART

In the semiconductor field, when a device is prepared by combining semiconductor chips having different circuits into one system, available are two techniques of SiP (system-in-package) in which another semiconductor chip is mounted on a semiconductor chip to obtain one package and POP in which plural semi-completed semiconductor chips are directly connected. SiP has the merits that since circuits are directly connected, power consumption is low and that circuit operation is quick.

In contrast with this, since POP is produced from a semi-completed package, combination of packages which are proved to be good items by quality inspection can be selected, and a yield of the completed device is not lowered. Further, POP is completed in a final mounting step, and therefore involved therein is the merit that instrument producers themselves can select combinations of semiconductor devices which exert performances meeting the features of the products, which is not expected from finished semiconductor devices.

On the other hand, POP prepared by combining peripheral terminal type semiconductor packages themselves such as QFP (quad flatpack package) and the like can be mounted on a mother board by arranging up a length of a peripheral terminal with a position of the other peripheral terminal. In contrast with this, in combination of grid terminal type semiconductor packages themselves such as BGA (ball grid array) and the like, not only terminals arranged on a lower surface interrupt connection of the semiconductor packages, but also the problem that it is difficult to secure a conduction passage of an upper semiconductor package with a mother board is involved therein.

Accordingly, put to practical use are POP type semiconductor packages comprising a structure in which a size of a principal part in a lower semiconductor package is reduced more than a size of a substrate (interposer) in upper and lower semiconductor packages and in which both semiconductor packages are connected to an outer circumference of the principal part in the lower semiconductor package by a conducting material for conducting the upper and lower substrates (refer to, for example, patent documents 1 to 5).

In the semiconductor device of the above POP system, a chip lamination number of a semiconductor package represented by BGA and the like which is positioned in a lower part in lamination tends to grow larger in order to raise more a packaging density.

A resin mold for protecting chips is increased in a height due to an increase in a lamination number, and a larger distance between substrates than a height of the resin mold has to be maintained. A method therefor includes a) enlarging a connection terminal in order to increase a connection terminal distance between upper and lower semiconductor packages so that it meets a thickness of the lower semiconductor package and b) controlling a mold height of the lower semiconductor package to a lower level by a reduction in a size of the chip and an increase in a density thereof.

However, if a connection terminal is increased in a size under an existing situation in which a pitch between connection terminals has to be narrowed by an increase in pins, short circuit between adjacent connection terminals themselves is caused. Further, a decrease in the thicknesses of a chip and a substrate brings about an increase in the cost to a large extent.

Accordingly, a connecting method having a low cost and a high reliability which can satisfy a height of a connection terminal distance and a narrow pitch thereof at the same time is required.

Patent document 1: Japanese Patent Application Laid-Open No. 319775/2004
Patent document 2: Japanese Patent Application Laid-Open No. 72190/2005
Patent document 3: Japanese Patent Application Laid-Open No. 197370/2005
Patent document 4: Japanese Patent Application Laid-Open No. 311066/2005
Patent document 5: Japanese Patent Application Laid-Open No. 340451/2005

### DISCLOSURE OF THE INVENTION

The present invention is to solve the problems described above, and an object thereof is to provide a wiring and connecting method by a spacer sheet which ensures an installation space between an upper semiconductor package and a lower semiconductor package in a complex type semiconductor device of a POP type and prevents short circuit between adjacent connection terminals and which can certainly wire and connect both semiconductor packages and allow a complex type semiconductor device of a POP type having a high packaging density to be provided by the above method.

Intensive researches repeated by the present inventors in order to achieve the object described above have resulted in finding that the object can be achieved by using a specific spacer sheet between substrates. The present invention has been completed based on the above knowledge.

That is, the essential points of the present invention are:

1. a complex type semiconductor device formed by laminating plural semiconductor packages, comprising

an upper semiconductor package which comprises a substrate for wiring and connecting provided with electrodes for conducting packages on a lower surface in the upper semiconductor package and a principal part of the upper semiconductor package disposed on an upper surface and/or a lower surface of the above substrate and which constitutes a relatively upper part,

a lower semiconductor package which comprises a substrate for wiring and connecting provided with electrodes for conducting packages on an upper surface in the lower semiconductor package and a principal part of the lower semiconductor package disposed on an upper surface and/or a lower surface of the above substrate and which constitutes a relatively lower part,

a spacer sheet which comprises a space part corresponding to the principal part of the upper semiconductor package and/or the principal part of the lower semiconductor package disposed between the adjacent upper and lower substrates and through holes disposed in a periphery of the above space part and allowing the electrodes oppositely disposed between the substrates to be communicated with each other and which is adhered onto the above substrates and inserted therebetween,

connection terminals which are provided in an inside of the through holes in the spacer sheet and which are used for conducting the substrates and

connection terminals for external connection which are formed on a lower surface of a substrate for wiring and connecting in a semiconductor package located in a lowermost part,

2. a semiconductor package which is used for a complex type semiconductor device formed by laminating plural semiconductor packages and which constitutes a relatively upper part of the complex type semiconductor device, comprising

a substrate for wiring and connecting in which electrodes for conducting packages are disposed on a lower surface,

a principal part of the semiconductor package disposed on an upper surface and/or a lower surface of the above substrate,

a spacer sheet which is adhered on a lower surface of the above substrate and which comprises a space part corresponding to a principal part of the above semiconductor package and/or a principal part of a semiconductor package disposed adjacent at a lower side of the above semiconductor package and through holes present in a periphery of the above space part and formed in positions corresponding to the electrodes and

connection terminals provided in an inside of the through holes in the spacer sheet,

3. a semiconductor package which is used for a complex type semiconductor device formed by laminating plural semiconductor packages and which constitutes a relatively lower part of the complex type semiconductor device, comprising

a substrate for wiring and connecting in which electrodes for conducting packages are disposed on an upper surface,

a principal part of the semiconductor package disposed on an upper surface and/or a lower surface of the above substrate,

a spacer sheet which is adhered on an upper surface of the above substrate and which comprises a space part corresponding to a principal part of the above semiconductor package and/or a principal part of a semiconductor package disposed adjacent at an upper side of the above semiconductor package and through holes present in a periphery of the above space part and formed in positions corresponding to the electrodes and

connection terminals provided in an inside of the through holes in the spacer sheet,

4. a spacer sheet for a complex type semiconductor device which is used by inserting between a substrate for wiring and connecting in an upper semiconductor package and a substrate for wiring and connecting in a lower semiconductor package in a complex type semiconductor device formed by laminating plural semiconductor packages, wherein:

it can be adhered to the substrate for wiring and connecting in the upper semiconductor package and the substrate for wiring and connecting in the lower semiconductor package; and it comprises

through holes which communicate electrodes disposed on mutually opposite surfaces of the substrate for wiring and connecting in the upper semiconductor package and the substrate for wiring and connecting in the lower semiconductor package and

a space part corresponding to a principal part of the upper semiconductor package disposed on a lower surface of the substrate for wiring and connecting in the upper semiconductor package and/or a principal part of the lower semiconductor package disposed on an upper surface of the substrate for wiring and connecting in the lower semiconductor package,

5. a set of spacer sheets for a complex type semiconductor device comprising a first spacer sheet which can be adhered to a substrate for wiring and connecting in a semiconductor package constituting an upper part of a complex type semiconductor device formed by laminating plural semiconductor packages and a second spacer sheet which can be adhered to a substrate for wiring and connecting in a semiconductor package constituting a lower part of the above complex type semiconductor device, wherein:

the first spacer sheet comprises through holes of an array corresponding to electrodes of the substrate for wiring and connecting in the above upper semiconductor package and a space part corresponding to a principal part of the upper semiconductor package and/or a principal part of the lower semiconductor package;

the second spacer sheet comprises through holes of an array corresponding to electrodes of the substrate for wiring and connecting in the above lower semiconductor package and a space part corresponding to a principal part of the upper semiconductor package and/or a principal part of the lower semiconductor package;

all of the through holes and the space part in the first spacer sheet and all of the through holes and the space part in the second spacer sheet assume plane symmetry; and

opposite surfaces of the first spacer sheet and the second spacer sheet are formed so that they can be adhered,

6. a set of the spacer sheets for a complex type semiconductor device according to the above item 5, wherein the through holes of the first and/or second spacer sheet are cone-shaped, and they can be barrel-shaped by laminating,
7. a sheet material used for the spacer sheet for a complex type semiconductor device according to any of the above items 4 to 6,
8. a production process for a complex type semiconductor device formed by laminating plural semiconductor packages, comprising:

a step of preparing an upper semiconductor package which comprises a substrate for wiring and connecting in the upper semiconductor package provided with electrodes for conducting packages on a lower surface and a principal part of the upper semiconductor package disposed on an upper surface and/or a lower surface of the above substrate and which constitutes a relatively upper part,

a step of preparing a lower semiconductor package which comprises a substrate for wiring and connecting in the lower semiconductor package provided with electrodes for conducting packages on an upper surface and a principal part of the lower semiconductor package disposed on an upper surface and/or a lower surface of the above substrate and which constitutes a relatively lower part,

a step in which connection terminals for conducting the above substrates are formed respectively on the electrodes of the substrates in the upper and lower semiconductor packages,

a step of preparing a spacer sheet comprising a space part corresponding to a principal part of the upper semiconductor package and/or a principal part of the lower semiconductor package which are disposed between the upper and lower substrates and through holes disposed in a periphery of the above space part which allow the electrodes oppositely disposed between the substrates to be communicated with each other and

a step in which the respective corresponding positions of the principal parts of the semiconductor packages and the space parts and the corresponding positions of the electrodes and the through holes are fitted to adhere the spacer sheet onto a lower surface of the substrate in the upper semiconductor package and adhere it onto an upper surface of the substrate in the lower semiconductor package and

9. A production process for a complex type semiconductor device formed by laminating plural semiconductor packages, comprising:

a step of preparing an upper semiconductor package comprising a substrate for wiring and connecting in the upper semiconductor package provided with electrodes for conducting packages on a lower surface and a principal part of the upper semiconductor package disposed on an upper surface and/or a lower surface of the above substrate and constituting a relatively upper part,

forming connection terminals on the electrodes, and

adhering a first spacer sheet onto a lower surface of the substrate in the upper semiconductor package,

the first spacer sheet comprising a space part corresponding to a principal part of the upper semiconductor package and/or a principal part of a lower semiconductor package disposed between the upper and lower substrates and through holes disposed in a periphery of the above space part, allowing the electrodes oppositely disposed between the substrates to be communicated with each other and being prepared to fit the positions of the principal part of the semiconductor package and the space part, and the corresponding positions of the electrodes and the through holes; and

a step of preparing a lower semiconductor package comprising a substrate for wiring and connecting in the lower semiconductor package provided with electrodes for conducting packages on an upper surface and a principal part of the lower semiconductor package disposed on an upper surface and/or a lower surface of the above substrate and constituting a relatively lower part,

forming connection terminals on the electrodes, and

adhering a second spacer sheet onto a lower surface of the substrate in the lower semiconductor package,

the second spacer sheet comprising a space part corresponding to a principal part of the upper semiconductor package and/or a principal part of the lower semiconductor package disposed between the upper and lower substrates and through holes disposed in a periphery of the above space part, allowing the electrodes oppositely disposed between the substrates to be communicated with each other and being prepared to fit the positions of the principal part of the semiconductor package and the space part, and the corresponding positions of the electrodes and the through holes;

wherein the first spacer sheet and the second spacer sheet are fitted in the corresponding positions of the through holes and oppositely faced to adhere them to each other, and the connection terminals brought into contact are fused and integrated.

According to the present invention, a wiring and connecting method by a spacer sheet in which in a complex type semiconductor device of a POP type, an installation space between an upper semiconductor package and a lower semiconductor package is ensured to prevent short circuit between adjacent connection terminals and in which both semiconductor packages are certainly wired and connected has come to be provided, and this has allowed a complex type semiconductor device of a POP type having a high packaging density to be provided.

### BRIEF DESCRIPTIONS OF THE DRAWINGS

FIG. 1 is a cross-sectional schematic drawing showing one example of a conventional complex type semiconductor device.

FIG. 2 is a cross-sectional schematic drawing showing one example of the complex type semiconductor device of the present invention.

FIG. 3 is a cross-sectional schematic drawing showing one example of the spacer sheet of the present invention.

FIG. 4 is a cross-sectional schematic drawing showing another example of the spacer sheet of the present invention.

FIG. 5 is a cross-sectional schematic drawing showing another example of the spacer sheet of the present invention.

FIG. 6 is a plain schematic drawing showing the spacer sheet of the present invention after providing through holes.

FIG. 7 is a plain schematic drawing showing the spacer sheet of the present invention after punching work of a pattern.

FIG. 8 is a step schematic drawing showing one example of the production process of the present invention.

FIG. 9 is a step schematic drawing showing another example of the production process of the present invention.

FIG. 10 is a step schematic drawing showing another example of the production process of the present invention.

FIG. 11 is a cross-sectional schematic drawing showing another example of the complex type semiconductor device of the present invention.

FIG. 12 is a cross-sectional schematic drawing showing another example of the complex type semiconductor device of the present invention.

FIG. 13 is a cross-sectional schematic drawing showing another example of the complex type semiconductor device of the present invention.

FIG. 14 is a cross-sectional schematic drawing showing another example of the complex type semiconductor device of the present invention.

### EXPLANATIONS OF THE CODES

1 Conventional complex type semiconductor device of a POP type
10 Complex type semiconductor device of a POP type according to the present invention
11 Lower semiconductor package having a low packaging density
12 Upper semiconductor package
13 Lower semiconductor package having a high packaging density
14 Wiring connecting part (conventional)
15 Wiring connecting part (present invention)
100, 100a, 100b Spacer sheet
101 Adhesive layer A
101a Adhesive layer Aa
101b Adhesive layer Ab
102 Adhesive layer B
102a Adhesive layer Ba
102b Adhesive layer Bb
103, 103a, 103b Base material layer
104 Through hole
105 Release film
106 Space part
111, 121, 131 Substrate
116, 126, 136 Principal part of semiconductor package
122, 132 Electrode
123 Semiconductor chip aa
124 Semiconductor chip ab
125, 135 Bonding wire
133 Semiconductor chip ba
134 Semiconductor chip bb
140, 141, 142 Connection terminal
150 Solder ball

### BEST MODE FOR CARRYING OUT THE INVENTION

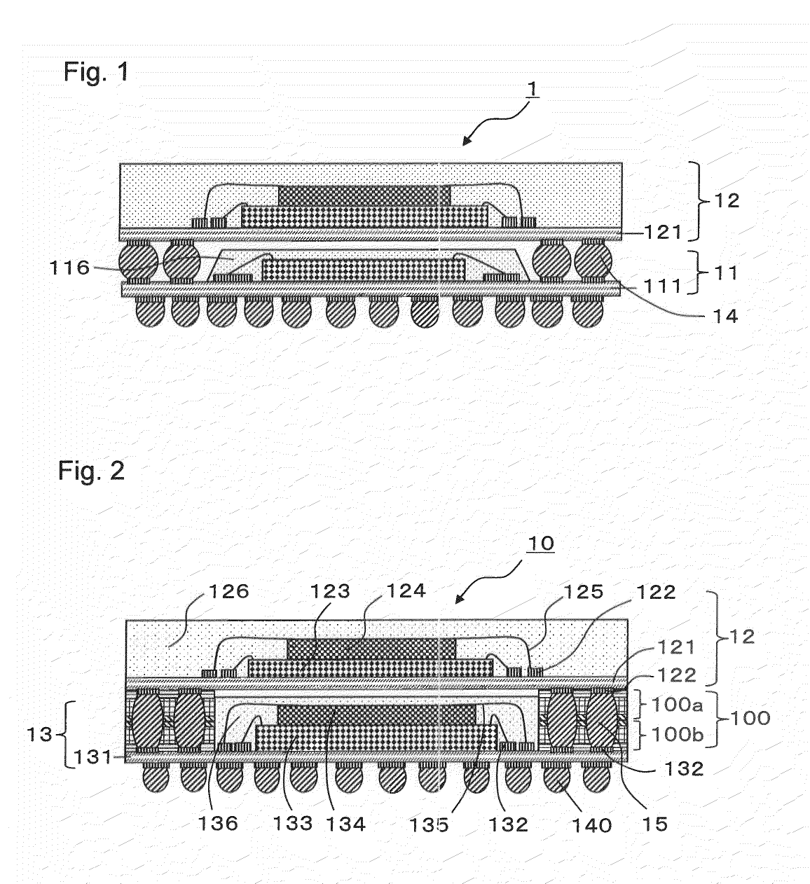

The complex type semiconductor device of the present invention, a semiconductor package and a spacer sheet used for the same and a production process for a complex type semiconductor device shall be explained with reference to the drawings. FIG. 1 is a cross-sectional schematic drawing showing one example of a conventional complex type semiconductor device, and FIG. 2 is a cross-sectional schematic drawing showing one example of the complex type semiconductor device of a POP type according to the present invention.

In FIG. 1, a conventional complex type semiconductor device 1 of a POP type is prepared by laminating an upper semiconductor package 12 on a lower semiconductor package 11 having a low packaging density via a wiring connecting part 14. Since the lower semiconductor package 11 has a low packaging density, a principal part 116 which is a mold thereof has a low height, and an interval between a substrate 111 which is an interposer of the lower semiconductor package 11 and a substrate 121 which is an interposer of the upper semiconductor package 12 is narrow. Since a pitch of the wiring connecting part 14 is wide, one ordinary solder ball is used as the wiring connecting part 14, and the wiring connecting part 14 is approximately spherical.

In contrast with this, the complex type semiconductor device 10 of a POP type according to the present invention is prepared, as shown in FIG. 2, by laminating an upper semiconductor package 12 on a lower semiconductor package 13 having a high packaging density via a wiring connecting part 15 having a vertically long rotator shape, particularly a vertically long spindle shape or an ellipsoidal shape. The upper semiconductor package 12 is constituted from a semiconductor chip aa 123, a semiconductor chip ab 124, a bonding wire 125, a substrate 121 which is an interposer and an electrode 122 provided thereon and a principal part 126 comprising a thermosetting polymer molding which seals the above members. The lower semiconductor package 13 comprises a semiconductor chip ba 133, a semiconductor chip bb 134, a bonding wire 135, a substrate 131 which is an interposer and an electrode 132 provided thereon and a principal part 136 comprising a thermosetting polymer molding which seals the above members. In this connection, the wiring connecting part 15 having a vertically long rotator shape makes connecting and wiring possible even if an interval between the substrate 121 which is an interposer of the upper semiconductor package 12 and the substrate 131 which is an interposer of the lower semiconductor package 13 is extended, and short circuit is not brought about even if a pitch between the adjacent wiring connecting parts 15 is narrow. By a spacer sheet 100, a solder ball is molded so that the above wiring connecting part 15 assumes a vertically long rotator shape, and in FIG. 2, the spacer sheet is constituted from a set of two sheets of a spacer sheet 100a adhered to the upper semiconductor package 12 and a spacer sheet 100b adhered to the lower semiconductor package 13.

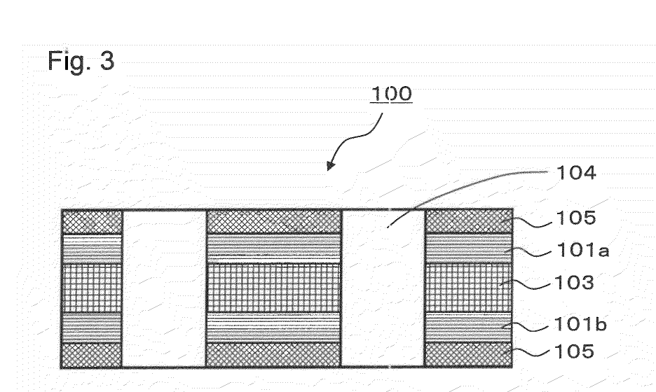

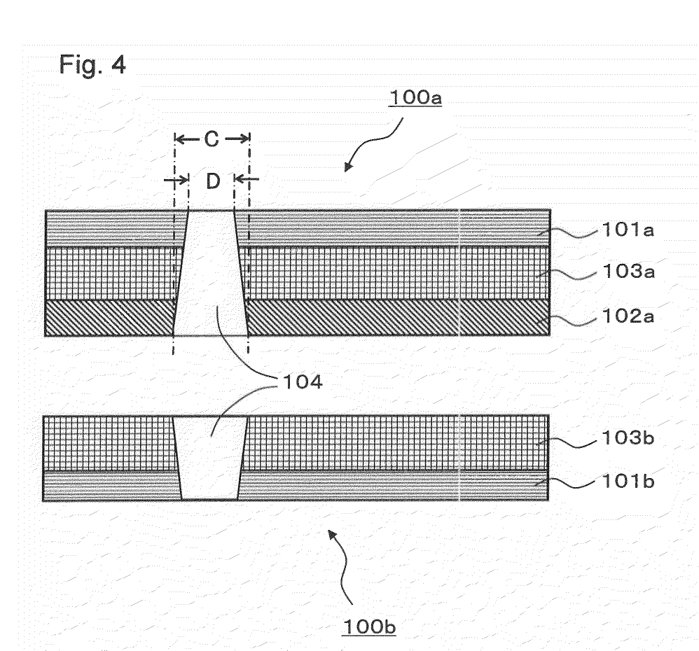

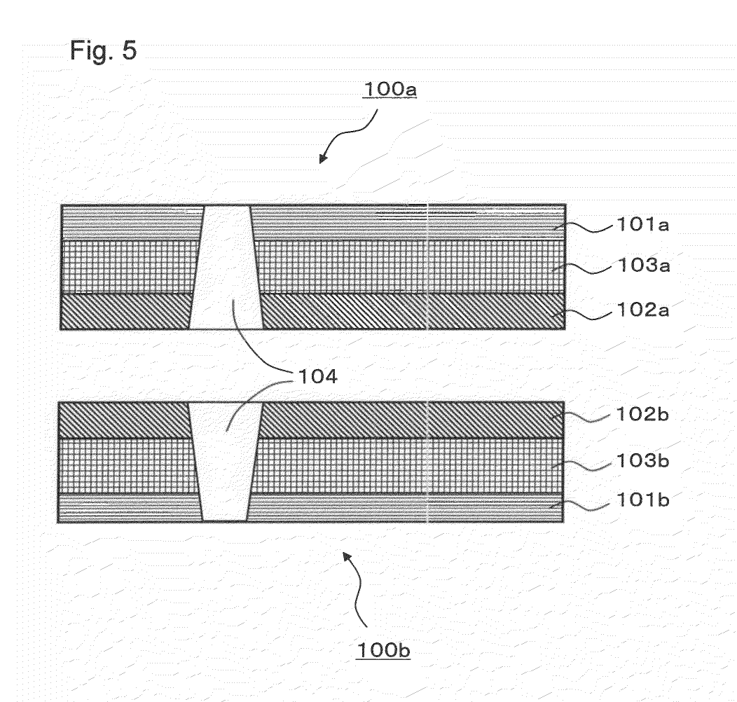

Next, the spacer sheet 100 of the present invention shall be explained with reference to FIG. 3 to 7. FIG. 3 is a cross-sectional schematic drawing showing the spacer sheet of the present invention, and FIGS. 4 and 5 are cross-sectional schematic drawings showing another examples of the spacer sheets of the present invention.

FIG. 3 shows an example of a five layer structure comprising a release film 105/an adhesive layer Aa (101a)/a base material layer 103/an adhesive layer Aa (101a)/a release film 105 which is a typical layer structure of the spacer sheet 100 of the present invention. The release film 105 is provided, if necessary, for the purpose of protecting the surface before use, and it is peeled immediately before using the spacer sheet 100. The spacer sheet 100 has a group of through holes 104, and the cylindrical through holes 104 are shown in FIG. 3, but the through holes shall not be restricted to them.

A means for forming the through holes 104 includes laser processing, drill processing, punching (perforating) processing and the like. Among them, laser processing carried out by using a carbon dioxide gas laser, a YAG laser, an excimer laser and the like is preferred since the through holes 104 having a high degree of precession are formed.

FIG. 4 and FIG. 5 show a spacer sheet 100a and a spacer sheet 100b which are used in a set of two sheets.

FIG. 4 shows an example of a three layer structure (a five layer structure including release films 105) of an adhesive layer B (102a)/a base material layer 103a/an adhesive layer Aa (101a) from the bottom as the spacer sheet 100a used for an upper semiconductor package 12 and an example of a two layer structure of an adhesive layer Ab (101b)/a base material layer 103b as the spacer sheet 100b used for a lower semiconductor package 13. The adhesive layer Aa (101a) and the adhesive layer Ab (101b) are used respectively in order to adhere to a substrate 121 or 131 of the semiconductor package 12 or 13. The release film 105 which is peeled in use may be provided, if necessary, on the respective surfaces of the adhesive layer Aa (101a), the adhesive layer B (102a) and the adhesive layer Ab (101b), and the adhesive layers Aa, Ab and B are protected, though not illustrated, by the release film 105s.

The spacer sheets 100a and 100b have a group of through holes 104, and the cone-shaped through holes 104 are shown in FIG. 4.

When a cross-sectional shape of the through holes 104 is cone-shaped as shown in FIG. 4, a through hole maximum diameter C thereof is preferably 100 to 500 μm, and a through hole minimum diameter D thereof is preferably 100 to 500 μm. A ratio (C/D) of C to D is preferably 1 to 2. A pitch of the above through holes 104 depends on an electrode constitution of the semiconductor package used, and it is preferably 30 to 5000 μm.

A thickness of the spacer sheet 100 depends on a thickness of the semiconductor package used and is varied depending on whether the spacer sheet 100 is used in a single sheet or a set of two sheets. When it is used in a single sheet, a thickness of the spacer sheet 100 is preferably 10 to 2000 μm. When it is used in a set of two sheets, the total of the thicknesses of the spacer sheets is preferably 100 to 2000 μm, and a thickness of one spacer sheet in a set of two sheets is preferably 50 to 1000 μm.

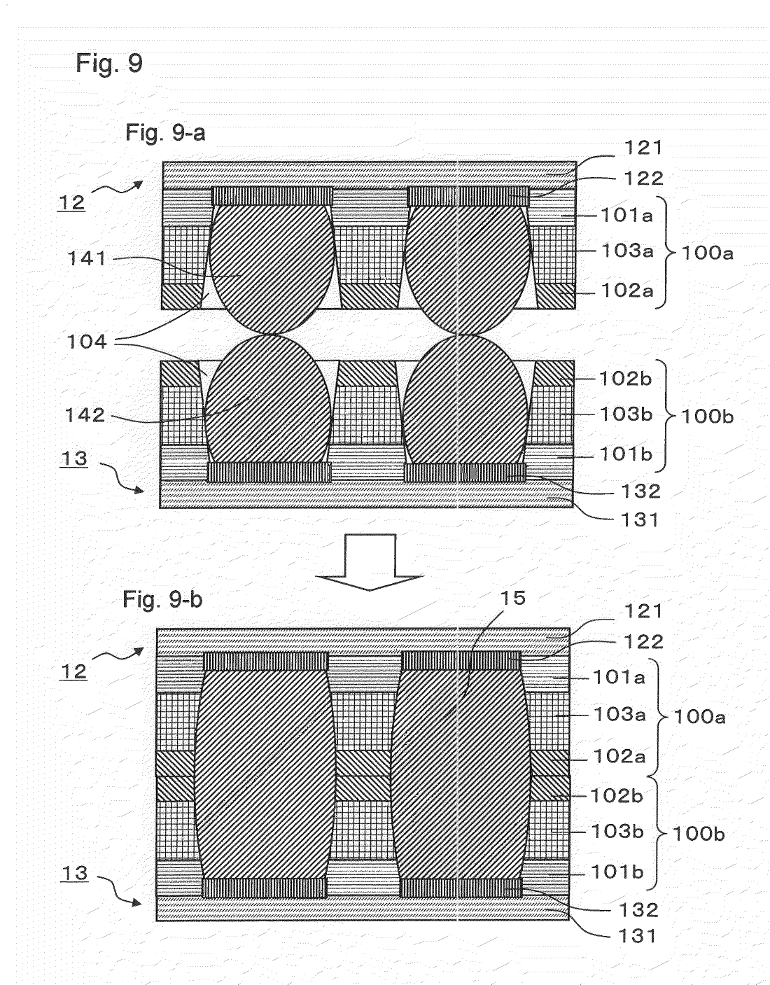

When the spacer sheet 100 is used in a set of two sheets, the through hole maximum diameter C is disposed preferably at a side opposite to the substrate as shown in FIG. 9-a described later, and the through hole minimum diameter D is disposed preferably at a substrate side. The above disposition prevents constriction from being formed at a wiring connecting part 15 formed by fusing connection terminals 141 and 142 described later, and therefore an impact resistance of the complex type semiconductor device is enhanced.

FIG. 5 shows a spacer sheet 100a which can be adhered to an upper semiconductor package 12 and a spacer sheet 100b which can be adhered to a lower semiconductor package 13, and both of the spacer sheet 100a and the spacer sheet 100b show an example of a three layer structure (a five layer structure including release films 105) of an adhesive layer A (101a or 101b)/a base material layer (103a or 103b)/an adhesive layer B (102a or 102b). The spacer sheet 100b assumes a layer structure obtained by reversing the spacer sheet 100a. In this case, lamination of the spacer sheet 100a and the spacer sheet 100b is carried out in the adhesive layers B 102a and 102b, and one adhesive layer comes to nothing, but they can be prepared respectively from the same sheet material, and therefore it is not disadvantageous in terms of the cost. Further, the release film 105 which is peeled in use may be provided, if necessary, on the respective surfaces of the adhesive layer A and the adhesive layer B.

The spacer sheets 100a and 100b have a group of through holes 104, and the cone-shaped through holes 104 are shown in FIG. 5.

The spacer sheets having constitutions comprising three layers or two layers have been explained in FIG. 3 to 5, and a sheet material used for the spacer sheet of the present invention is preferably provided with a thickness, a strength and an insulating property which are required to the sheet. The layer constitution of the spacer sheet is not limited to 2 to 3 layers, and the spacer sheet is preferably provided with at least one adhesive layer. That is, it may be a layer constitution comprising a single layer of the adhesive layer A or 2 layers of the adhesive layer A and the adhesive layer B. Further, the layer constitution may comprise 4 to 8 layers obtained by laminating a unit of an adhesive layer and a base material layer, and it may be a multilayer constitution of 5 to 9 layers obtained by further laminating thereon an adhesive layer. The above layer constitutions are irrespective of whether the spacer sheet 100 is used in a single sheet or a set of two sheets.

The adhesive layer A101 and/or the adhesive layer B102 in the sheet material used for the spacer sheet 100 of the present invention is preferably a layer showing a strong adhesive property to the substrate or the adhesive layer A101 or the adhesive layer B102, and they comprise preferably a resin composition containing at least one resin selected from the group consisting of (meth)acrylic resins, silicone resins, epoxy resins, polyimide resins, maleimide resins, bismaleimide resins, polyamideimide resins, polyetherimide resins, polyimide-isoindroxonazolinedioneimide resins, polyvinyl acetate resins, polyvinyl alcohol resins, polyvinyl chloride resins, polyacrylic ester resins, polyamide resins, polyvinyl butyral resins, polyethylene resins, polypropylene resins and polysulfonic acid resins.

The adhesive layer comprising the above resins may be pressure-sensitive adhesive (sticky) or non-pressure-sensitive adhesive at ambient temperature. Further, it may be either thermoplastic or thermosetting. A thickness of the adhesive layer A101 (single layer) at a side which is stuck to the substrate is preferably 10 to 200 μm, and a thickness of the adhesive layer B102 (single layer) is preferably 5 to 200 μm.

The same resin composition may be used for the adhesive layer A101 and the adhesive layer B102 or different resin compositions may be used therefor.

A (meth)acrylic resin composition can be turned into either a pressure-sensitive adhesive or a non-pressure-sensitive adhesive. Compositions in which copolymers obtained by copolymerizing various (meth)acrylic ester monomers with copolymerizable monomers blended if necessary are used as principal raw materials and in which additives such as a cross-linking agent and others are suitably blended are suitably used as the (meth)acrylic resin composition for a pressure-sensitive adhesive. In this connection, (meth)acrylic means acrylic or methacrylic.

Used as the (meth)acrylic ester monomers are, for example, acrylic alkyl esters such as methyl acrylate, ethyl acrylate, butyl acrylate, 2-ethylhexyl acrylate, octyl acrylate, cyclohexyl acrylate, benzyl acrylate and the like and methacrylic alkyl esters such as butyl methacrylate, 2-ethylhexyl methacrylate, cyclohexyl methacrylate, benzyl methacrylate and the like.

Vinyl acetate, vinyl propionate, vinyl ethers, styrene and acrylonitrile are suitably used as the copolymerizable monomers, for example, as the monomers having no functional groups.

Suitably used as the copolymerizable monomers having functional groups are, for example, carboxyl group-containing monomers such as acrylic acid, methacrylic acid, crotonic acid, maleic acid, fumaric acid, itaconic acid and the like, hydroxyl group-containing monomers such as 2-hydroxyethyl (meth)acrylate, 2-hydroxypropyl(meth)acrylate, 2-hydroxybutyl (meth)acrylate, N-methylolacrylamide, allyl alcohol and the like, tertiary amino group-containing monomers such as dimethylaminopropyl(meth)acrylate and the like, N-substituted amide group-containing monomers such as acrylamide, N-methyl(meth)acrylamide, N-methoxymethyl(meth)acrylamide, N-octylacrylamide and the like and epoxy group-containing monomers such as glycidyl methacrylate and the like.

The cross-linking agents used for the (meth)acrylic resin composition include isocyanate compounds, epoxy compounds, metal chelate compounds, amine compounds, hydrazine compounds, aldehyde compounds, metal alkoxide compounds, metal salts and the like. Among them, the isocyanate compounds and the epoxy compounds are preferred.

A silicone resin composition can be turned as well into either a pressure-sensitive adhesive or a non-pressure-sensitive adhesive. The silicone resin composition which is turned into a pressure-sensitive adhesive is constituted usually from an adhesive principal agent comprising a mixture of a silicone resin component and a silicone gum component and additives such as a cross-linking agent, a catalyst and the like. The silicone resin composition includes an addition reaction type composition, a condensation reaction type composition, a peroxide cross-linking type composition and the like according to a cross-linking system, and addition reaction type silicone resin compositions are preferred in terms of a productivity and the like. The addition reaction type silicone resin composition is cross-linked by a silicone gum component or a silicone resin component which contains a vinyl group and in which a hydrosilyl group (SiH group) is a cross-linking site. Further, the addition reaction type silicone resin composition is blended, if necessary, with a catalyst such as a platinum catalyst and the like in order to accelerate the reaction.

A polyimide resin is usually non-pressure-sensitive adhesive and thermoplastic, and therefore it can be adhered by bringing into tight contact with the substrate and heating. The polyimide resin is preferably an aliphatic polyimide resin having a good heating adhesive property.

An epoxy resin alone is non-pressure-sensitive adhesive, and it is thermosetting due to a reactivity of an oxyrane ring. Bisphenol A type epoxy resins, o-cresol novolac type epoxy resins and the like are preferred as the epoxy resin, and they are used usually in the form of a thermosetting resin composition prepared by blending them with a curing agent such as dicyandiamide and the like and a curing accelerating agent such as 2-phenyl-4,5-hydroxymethylimidazole and the like.

Thermosetting type pressure-sensitive adhesives can be used as the adhesive layer A101 and/or the adhesive layer B102 used in the present invention. The thermosetting type pressure-sensitive adhesive can be used usually by blending a pressure-sensitive adhesive with a thermosetting adhesive. For example, a blended matter of the (meth)acrylic resin composition and the epoxy resin each described above is preferred.

The base material layer 103 of the sheet material used for the spacer sheet 100 of the present invention is preferably a layer having a dimensional stability, a handling aptitude and a processing aptitude and fulfilling a performance to maintain a thickness, and the layer having a high mechanical strength is preferred. A melting point of the base material layer 103 or a thermal decomposition temperature of the base material layer 103 having no melting point is preferably 150° C. or higher, more preferably 200° C. or higher. A high dimensionally stable and heat resistant film of a polyimide resin, particularly an aromatic polyimide resin, a polyethylene terephthalate resin, a polyethylene naphthalate resin, a polymethylpentene resin, a fluororesin, a liquid crystal polymer, a polyetherimide resin, an aramid resin, a polyetherketone resin, a polyphenylene sulfide resin and the like is suitably used for the base material layer 103. A mechanical strength of the base material layer 103 is preferably 100 MPa or more in terms of a Young's modulus at room temperature. A thickness of the base material layer 103 is suitably selected according to a thickness of the spacer sheet 100 desired.

The release film 105 of the sheet material preferably used for the spacer sheet 100 of the present invention is releasably laminated on the surface of the adhesive layer A101 and/or the adhesive layer B102 in the spacer sheet 100 to protect the surface of the adhesive layer A101 and/or the adhesive layer B102 from adhesion of foreign matters, scratching and deformation. A film on which a release agent such as a silicone resin, an alkyd resin and the like is applied is suitably used as the release film 105, and particularly a polyethylene terephthalate film and a polyethylene naphthalate film which are subjected to release treatment are preferred. A thickness of the release film 105 is preferably 10 to 200 μm.

The adhesive layer A101 and/or the adhesive layer B102 in the spacer sheet 100 can be prevented from being stained by providing the release film, and it becomes easy to handle.

A carrier film used in forming the adhesive layer A101 and/or the adhesive layer B102 may be laminated as it is and diverted to the release film.

The spacer sheet 100 of the present invention is insulating and has preferably a volume resistivity of 10¹² Ω·cm or more. The adhesive layer and the base material layer of the sheet material used for the spacer sheet 100 of the present invention are insulating as well, and they each have preferably a volume resistivity of 10¹² Ω·cm or more.

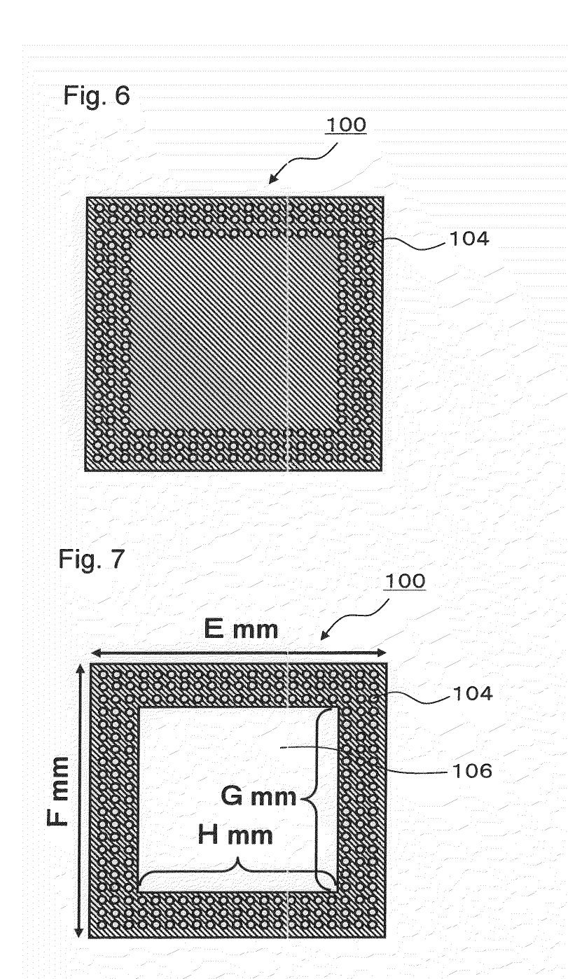

FIG. 6 is a plain schematic drawing showing the spacer sheet 100 of the present invention after providing through holes, and FIG. 7 is a plain schematic drawing showing the spacer sheet 100 of the present invention shown in FIG. 6 after a punching work of a pattern corresponding to a principal part of the semiconductor package. A space part 106 is provided in the spacer sheet 100.

In FIG. 7, through holes 103 are arranged in triple lines, but they may be arranged in a single line, double lines or quadruple or more lines. The spacer sheet 100 on which the through holes are provided is further subjected to a punching work of a pattern corresponding to a principal part of the semiconductor package to provide the space part 106. In the punching work of the pattern, it is punched out by a punching (perforating) work according to a shape of a principal part 126 or 136 of an upper or lower semiconductor package. Assuming that an outer circumference is E mm×F mm and that an inner circumference (an outer circumference of the space part 105) is G mm×H mm, usually E and F are 5 to 50 mm, and G and H are 3 to 48 mm. A shape thereof is approximately square in many cases.

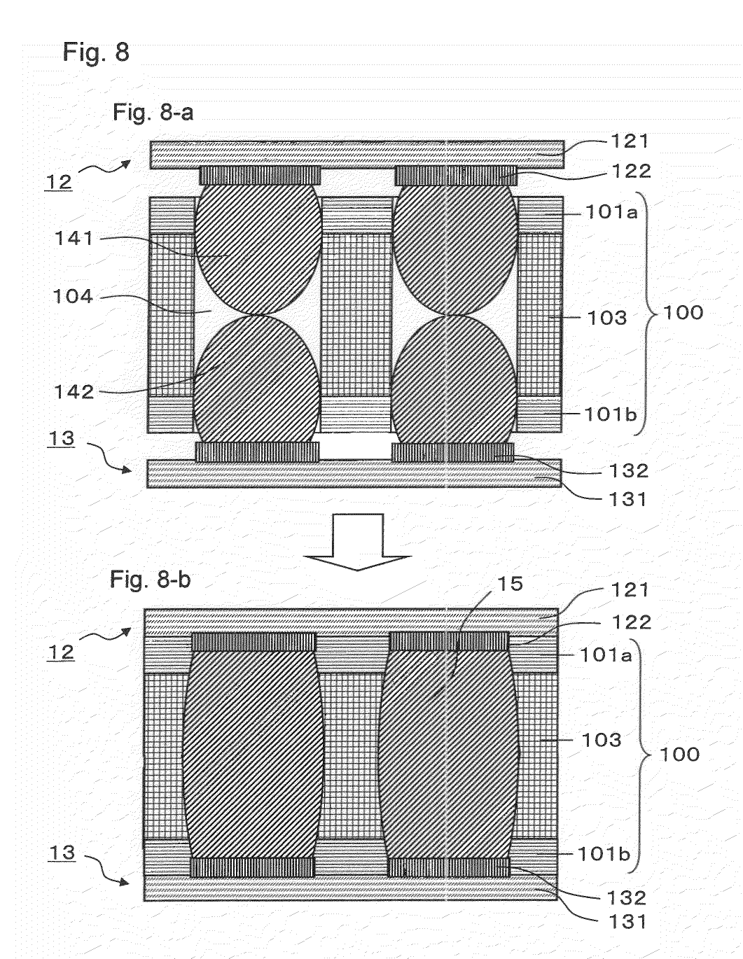

Next, a first production process for the complex type semiconductor device of the present invention shall be explained with reference to FIG. 8. FIG. 8 is a step schematic drawing showing one example of the production process of the present invention. FIG. 8-a shows a state prior to a step in which a connection terminal 141 of a substrate in an upper semiconductor package is fused with a connection terminal 142 of a substrate in a lower semiconductor package, and FIG. 8-b shows a state after finishing the step of fusing the above connection terminals.

The production process of the present invention is a production process for a complex type semiconductor device formed by laminating plural semiconductor packages, and it is not restricted to a case in which the semiconductor packages are laminated in 2 layers and may be a case in which the semiconductor packages are laminated in 3 layers or more, for example, 3 to 5 layers. The respective steps in a case in which the semiconductor packages are laminated in 2 layers shall be explained below.

(1) First, prepared is an upper semiconductor package 12 which comprises a substrate 121 for wiring and connecting in the upper semiconductor package 12 provided with electrodes for conducting packages on a lower surface and a principal part 126 of the upper semiconductor package disposed on an upper surface and/or a lower surface of the above substrate and which constitutes a relatively upper part.
(2) Further, prepared is a lower semiconductor package 13 which comprises a substrate 131 for wiring and connecting in the lower semiconductor package 13 provided with electrodes for conducting packages on an upper surface and a principal part 136 of the lower semiconductor package disposed on an upper surface and/or a lower surface of the above substrate and which constitutes a relatively lower part.
(3) Next, a flux is applied on electrodes 122 and 132 of the substrates in the upper and lower semiconductor packages by a screen printing method, and then a solder ball is set thereon. It is put in an IR reflow (maximum temperature: 260° C., manufactured by Senju Metal Industry Co., Ltd.) to fuse the solder ball on the electrode 122, whereby ball-shaped connection terminals (bumps) 141 and 142 for conducting the electrodes 122 and 132 described above are formed respectively.
(4) Separately from the steps (1) to (3) described above, a spacer sheet 100 comprising a space part 106 (not illustrated) corresponding to the principal part 126 of the upper semiconductor package and/or the principal part 136 of the lower semiconductor package disposed between upper and lower substrates 121 and 131 and through holes 104 disposed in a periphery of the above space part which allow the electrodes 122 and 132 oppositely disposed between the substrates 121 and 131 to be communicated with each other is prepared by providing the through holes 104 and the space part 106. In FIG. 8, the spacer sheet 100 shown in FIG. 3 which is used in a single sheet is used.
(5) The upper semiconductor package 12, the lower semiconductor package 13 and the spacer sheet 100 each prepared in the steps (1) to (4) described above are used, and the respective corresponding positions of the principal parts 126 and/or 136 of the semiconductor packages and the space part 106 and the corresponding positions of the electrodes 122 and 132 (or the connection terminals 141 and 142) and the through holes 104 are fitted, and the spacer sheet 100 is inserted. In this case, the spacer sheet 100 is adhered onto either of a lower surface side of the substrate 121 and an upper surface side of the substrate 131, and then the other substrate is adhered thereon, whereby the spacer sheet assumes the state that it is inserted. Connection terminals may be provided on the substrate adhered first to the spacer sheet 100 before adhered, or connection terminals may be provided in a stage prior to adhering the other substrate after adhering first the substrate. The connection terminals are provided in advance on the substrate adhered later before adhered.
(6) Next, a set of the upper semiconductor package 12 and the lower semiconductor package 13 into which the spacer sheet 100 is inserted is put in an IR reflow (maximum temperature: 260° C., manufactured by Senju Metal Industry Co., Ltd.) to fuse the connection terminal 141 of the substrate 121 in the upper semiconductor package 12 with the connection terminal 142 of the substrate 131 in the lower semiconductor package 13, whereby a wiring connecting part 15 is formed, and the spacer sheet 100 is adhered to a lower surface of the substrate 121 in the upper semiconductor package 12 and adhered to an upper surface of the substrate 131 in the lower semiconductor package 13.

As described above, the first production process for the complex type semiconductor device of the present invention comprises the steps (1) to (6) described above.

Further, a second production process for the complex type semiconductor device of the present invention shall be explained with reference to FIG. 9. FIG. 9 is a step schematic drawing showing the production process of the present invention. FIG. 9-a shows a state prior to a step in which a connection terminal of a substrate in an upper semiconductor package is fused with a connection terminal of a substrate in a lower semiconductor package, and FIG. 9-b shows a state after finishing the step of fusing the above connection terminals. A spacer sheet 100a and a spacer sheet 100b in FIG. 9 assume the layer structure shown in FIG. 5.

The second production process of the present invention is also a production process for a complex type semiconductor device formed by laminating plural semiconductor packages, and it is not restricted to a case in which the semiconductor packages are laminated in 2 layers and may be a case in which the semiconductor packages are laminated in 3 layers or more, for example, 3 to 5 layers. The respective steps in a case in which the semiconductor packages are laminated in 2 layers shall be explained below.

(1) Prepared is an upper semiconductor package 12 which comprises a substrate 121 for wiring and connecting in the upper semiconductor package 12 provided with electrodes 122 for conducting packages on a lower surface and a principal part 126 of the upper semiconductor package disposed on an upper surface and/or a lower surface of the above substrate and which constitutes a relatively upper part.
(2) Next, after applying a flux on the above electrode 122 by a screen printing method, a solder ball is set thereon, and it is put in an IR reflow (maximum temperature: 260° C., manufactured by Senju Metal Industry Co., Ltd.) to fuse the solder ball on the electrode 122, whereby a ball-shaped connection terminal 141 (bump) is formed.
(3) In addition to the step (2), a first spacer sheet 100a comprising a space part 106 corresponding to a principal part 126 of the upper semiconductor package and/or a principal part 136 of a lower semiconductor package disposed between the upper and lower substrates 121 and 131 and through holes 104 disposed in a periphery of the above space part 106 which allow the electrodes 122 and 132 oppositely disposed between the substrates 121 and 131 to be communicated with each other is prepared to fit the positions of the principal part 126 of the semiconductor package and the space part and the corresponding positions of the electrodes and the through holes to adhere the first spacer sheet 100a onto a lower surface of the substrate 121 in the upper semiconductor package 12.

In the steps (2) and (3), after forming the connection terminal 141, the first spacer sheet 100a may be adhered onto the lower surface of the substrate 121 in the upper semiconductor package 12, or after the first spacer sheet 100a is adhered onto the lower surface of the substrate 121 in the upper semiconductor package 12, a solder ball may be fused on the electrode 122 after spraying and applying a flux, if necessary, on the electrode 122 and the though holes 104 to form the ball-shaped connection terminal 141 (bump). Accordingly, the step (2) and the step (3) may be regarded as a single step.

(4) Separately from the steps (1) to (3), prepared is a lower semiconductor package 13 which comprises a substrate 131 for wiring and connecting in the lower semiconductor package 13 provided with electrodes 132 for conducting packages on an upper surface and a principal part 136 of the lower semiconductor package disposed on an upper surface and/or a lower surface of the above substrate and which constitutes a relatively lower part.
(5) Next, a flux is applied on the above electrodes 132 by a screen printing method, and then a solder ball is set thereon. It is put in an IR reflow (maximum temperature: 260° C., manufactured by Senju Metal Industry Co., Ltd.) to fuse the solder ball on the electrode 132, whereby a ball-shaped connection terminal 142 (bump) is formed.
(6) In addition to the step (5), a second spacer sheet 100b comprising a space part 106 corresponding to a principal part 126 of the upper semiconductor package and/or a principal part 136 of the lower semiconductor package disposed between the upper and lower substrates 121 and 131 and through holes 104 disposed in a periphery of the above space part 106 which allow the electrodes 122 and 132 oppositely disposed between the substrates 121 and 131 to be communicated with each other is prepared to fit the positions of the principal part 136 of the semiconductor package and the space part and the corresponding positions of the electrodes and the through holes to adhere the second spacer sheet 100b onto an upper surface of the substrate 131 in the upper semiconductor package 13.

Also in the steps (5) and (6), after forming the connection terminal 142 as is the case with the step (2) and the step (3), the second spacer sheet 100b may be adhered onto the upper surface of the substrate 131 in the lower semiconductor package 13, or after the second spacer sheet 100b is adhered onto the upper surface of the substrate 131 in the lower semiconductor package 13, a solder ball may be fused on the electrode 132 after spraying and applying a flux, if necessary, on the electrode 132 and the though holes 104 to form the ball-shaped connection terminal 142 (bump). Accordingly, the step (5) and the step (6) may be regarded as a single step.

(7) Next, in the upper semiconductor package 12 loaded with the first spacer sheet 100a and the lower semiconductor package 13 loaded with the second spacer sheet 100b, the first spacer sheet 100a and the second spacer sheet 100b are oppositely faced by fitting the positions of the corresponding though holes 104, and they are put in an IR reflow (maximum temperature: 260° C., manufactured by Senju Metal Industry Co., Ltd.) to fuse the connection terminals 141 of the substrate 121 in the upper semiconductor package 12 with the connection terminals 142 of the substrate 131 in the lower semiconductor package 13, whereby wiring connecting parts 15 are formed. The first spacer sheet 100a and the second spacer sheet 100b which are oppositely faced by fitting the positions of the corresponding though holes are adhered with each other.

As described above, the second production process for the complex type semiconductor device of the present invention comprises the steps (1) to (7) described above.

In the production process of the present invention, the sizes of the connection terminal 141 and the connection terminal 142 may be the same or different as shown in FIG. 8-a and FIG. 9-a.

In FIG. 9-a, the spacer sheet 100a and the spacer sheet 100b may comprise the same layer constitution and the same material and may comprise different layer constitutions and different materials. The adhesive layer Aa (101a), the adhesive layer Ab (101b), the adhesive layer Ba (102a) and the adhesive layer Bb (102b) may comprise as well the same material and have the same thickness, and they may comprise different materials and have different thicknesses. The same shall apply to the base material layers 103a and 103b.

A material used for the connection terminals 141 and 142 according to the present invention is preferably a solder ball. The solder ball can be selected from various solder compositions. It can widely be selected from, for example, a tin-silver eutectic solder and a tin-silver-copper eutectic solder each of which is a lead-free solder, a tin-lead eutectic solder and the like. A form of the solder ball is usually spherical. The solder ball has an average particle diameter of preferably 50 to 500 μm, particularly preferably 100 to 400 μm.

The best embodiment of the present invention has been explained above, but the present invention shall not be restricted to the above explanations and can assume various embodiments.

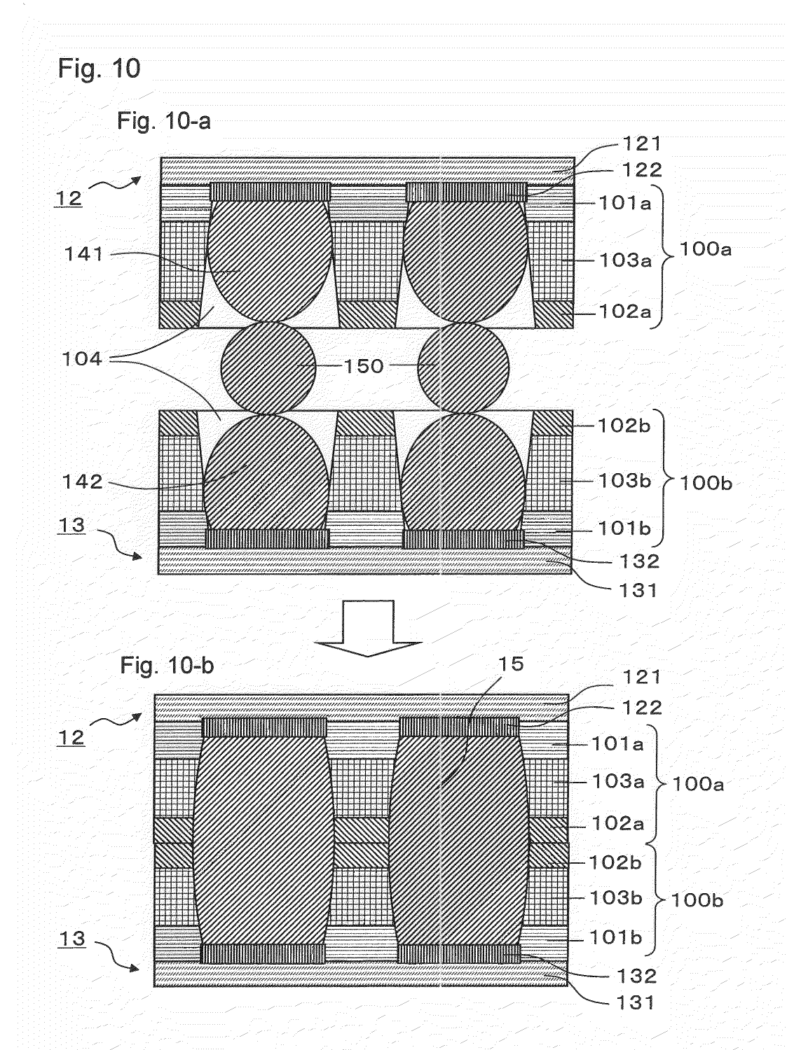

For example, the connection terminals shown in FIG. 8-a and FIG. 9-a show a constitution in which two connection terminals of the connection terminal 141 provided on a lower surface of the substrate 121 in the upper semiconductor package 12 and the connection terminal 142 provided on an upper surface of the substrate 131 in the lower semiconductor package 13 make one set. In contrast with this, when the spacer sheet is thick as shown in FIG. 10-a, a plurality of 3 or more connection terminals may be one set. To be specific, another connection terminal (solder ball 150) is superposed, as shown in FIG. 10-a, on the connection terminal 142 inserted into the through hole 104 of the spacer sheet 100b and subjected to IR reflow to integrate them, or the spacer sheet 100a of the upper semiconductor package 12 is put directly on another superposed connection terminal (solder ball) and adhered to the spacer sheet 100b, and the connection terminal 141 is brought into contact with another connection terminal (solder ball 150) and subjected to IR reflow, whereby plural connection terminals can integrally be molded. The manner described above manages without using the solder ball having a large diameter as the connection terminal and prevents a distance between the substrates and a margin of a pitch between the connection terminals from being reduced by a diameter of the solder ball.

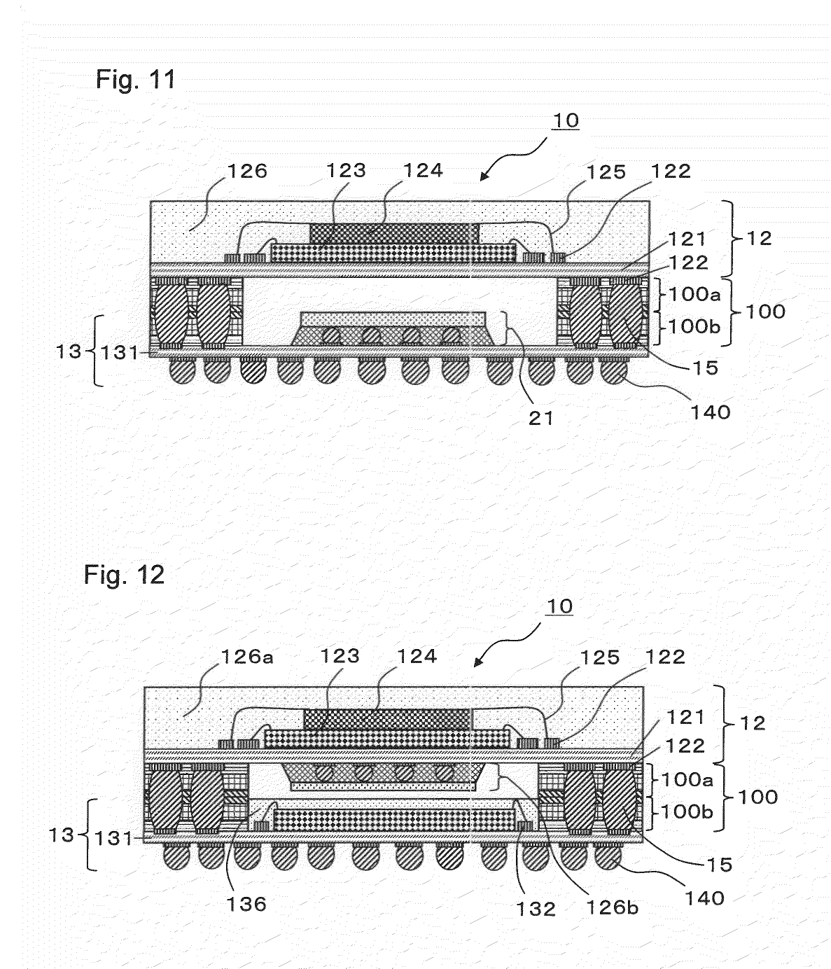

Also, in the explanations and the drawings described above, a principal part of the semiconductor package has been explained as a mold part of the semiconductor package including the semiconductor chip, and as shown in FIG. 11, a chip itself (flip chip 21) formed on the substrate by flip chip bonding may be a principal part of the semiconductor package.

Further, the upper semiconductor package 12 and the lower semiconductor package 13 assume a constitution in which both of the principal parts thereof are provided at an upper surface side of the substrate, and as shown in FIG. 12 to 14, they may assume a POP structure in which the principal parts are provided inversely on a lower surface of the substrate or a POP structure in which the principal parts are provided on both surfaces of the substrate.

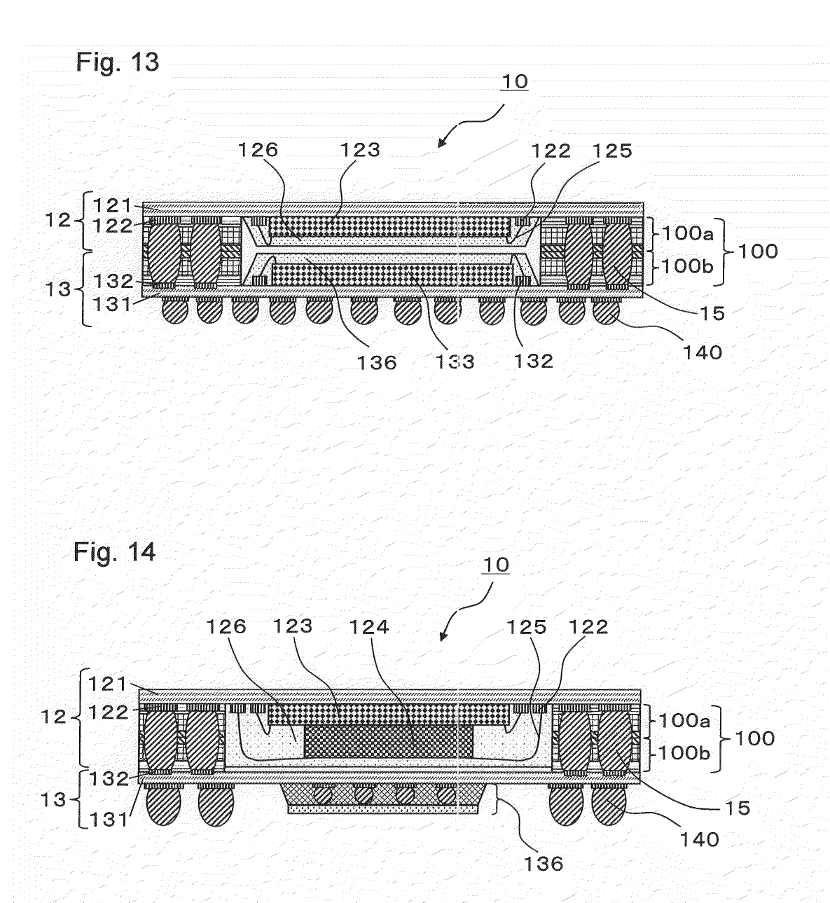

FIG. 12 shows a case in which the principal parts 126a and 126b of the upper semiconductor package 12 are disposed on both upper and lower surfaces and in which a principal part of the lower semiconductor package 13 is disposed on the upper surface. FIG. 13 shows a case in which a principal part of the upper semiconductor package 12 is disposed on the lower surface and in which a principal part of the lower semiconductor package 13 is disposed on the upper surface to allow the semiconductor packages to be opposed. Further, FIG. 14 shows a case in which the principal parts of both the upper semiconductor package 12 and the lower semiconductor package 13 are provided on the lower surfaces. Also in the case of the POP structure shown in FIG. 12 to 14 described above, the spacer sheet 100 is used between the substrates. Also in such the POP structure as described above, the spacer sheet 100 may be provided in a set of two sheets as shown in FIG. 11 to 14 or may be provided in a single sheet as shown in FIG. 8.

### EXAMPLES

Next, the present invention shall be explained in further details with reference to examples, but the present invention shall by no means be restricted by these examples.

The possibility of electrical connection and a distance between the upper and lower substrates were measured according to the following methods.

### <Possibility of Electrical Connection>

Conduction between the probes of the upper and lower substrates was confirmed by means of a digital multimeter digital high tester, manufactured by HIOKI E.E. CORPORATION).

### <Distance Between Upper and Lower Substrates>

A cross section of the connection terminal part was allowed to appear by polishing a cross section of the complex type semiconductor device, and then a distance between the upper and lower substrates was measured by means of a digital microscope.

The following materials were used for the adhesive layers, the base material layers and the release films in Examples 1 to 4 and Comparative Examples 1 to 3.

### 1. Adhesive Layer:

### (1) Adhesive Layer α: Acryl Base Pressure-Sensitive Adhesive

Used was a blended matter prepared by blending 100 parts by mass of an acryl base adhesive principal agent (Oribain BPS5375, manufactured by Toyo Ink MFG. Co., Ltd.) with 2 parts by mass of an organic polyvalent isocyanate cross-linking agent (Coronate L, manufactured by Nippon Polyurethane Industry Co., Ltd.). The volume resistivity was 2×10¹⁴ Ω·cm.

### (2) Adhesive Layer β: Silicone Base Pressure-Sensitive Adhesive

Used was a blended matter prepared by blending 100 parts by mass of an addition reaction type silicone adhesive principal agent (SD4580, manufactured by Dow Corning Toray Co., Ltd.) with 1 part by mass of a platinum catalyst (RX212, manufactured by Dow Corning Toray Co., Ltd.). The volume resistivity was 8×10¹⁵ Ω·cm.

### (3) Adhesive Layer γ: Thermoplastic Adhesive

A thermally adhesive polyimide base resin (UL27, manufactured by Ube Industries, Ltd.) was used. The volume resistivity was 1×10¹⁵ Ω·cm.

### (4) Adhesive Layer δ: Thermosetting Adhesive

Used was a blended matter of an acryl copolymer/a liquid epoxy resin A/a solid epoxy resin B/a solid epoxy resin C/a curing agent/a curing accelerating agent/a silane coupling agent/polyisocyanate=20/30/40/10/1/1/0.6/0.5 (unit: parts by mass). The volume resistivity was 7×10¹³ Ω·cm.

The following respective materials were used for the blended matter of the adhesive layer δ.

Acryl copolymer: COPONYL-2359-6, manufactured by Nippon Synthetic Industry Co., Ltd.

Liquid epoxy resin A: acryl rubber fine particle-dispersed bisphenol A type liquid epoxy resin (Eposet BPA328, manufactured by Nippon Shokubai Co., Ltd., epoxy equivalent: 230)

Solid epoxy resin B: bisphenol A type solid epoxy resin (Epikote 1055, manufactured by Japan Epoxy Resins Co., Ltd., epoxy equivalent: 875 to 975)

Solid epoxy resin C: o-cresol novolac type epoxy resin (EOCN-104S, manufactured by Nippon Kayaku Co., Ltd., epoxy equivalent: 213 to 223)

Curing agent: dicyandiamide (Adeka Hardener 3636AS, manufactured by Asahi Denka Co., Ltd.)

Curing accelerating agent: 2-phenyl-4,5-hydroxymethylimidazole (Curesol 2PHZ, manufactured by Shikoku Chemicals Corporation)

Silane coupling agent: MKC Silicate MSEP2, manufactured by Mitsubishi Chemical Corporation)

Polyisocyanate: Oribain BHS8515, manufactured by Toyo Ink MFG. Co., Ltd.

### 2. Base Material Layer:

The following materials were used for the base material layers.

(1) Base material layer α: polyimide film (UPILEX S-75, manufactured by Ube Industries, Ltd.), thickness: 75 μm, Young's modulus: 9000 MPa, volume resistivity: 1×10¹⁷ Ω·cm.
(2) Base material layer β: polyimide film (UPILEX S-125, manufactured by Ube Industries, Ltd.), thickness: 125 μm, Young's modulus: 9000 MPa, volume resistivity: 1×10¹⁷ Ω·cm.

### 3. Release Film:

The following materials were used for the release films.

(1) Release film α: SP-PET3811, manufactured by Lintec Corporation, thickness: 38 μm.
(2) Release film β: Filmbyna 38E-0100YC, manufactured by Fujimori Kogyo Co., Ltd., thickness: 38 μm.
(3) Release film γ: SP-PET38AL-5, manufactured by Lintec Corporation, thickness: 38 μm.

### 4. Solder Ball:

The following material was used for the solder ball for the connection terminals.

Lead-free solder (zinc-silver-copper): Eco Solder Ball M705, manufactured by Senju Metal Industry Co., Ltd., diameter: 260 μm, 280 μm, 300 μm.

### 5. Lower BGA Semiconductor Package:

The following package was used as the lower BGA semiconductor package.

Size: 14×14 mm, land number: 152, land pitch: 0.65 mm, land diameter: 300 μm, length from a land end to a package end: 350 μm, substrate thickness: 310 μm, mold height: about 450 μm.

### 6. Upper BGA Semiconductor Package:

The following package was used as the upper BGA semiconductor package.

Size: 14×14 mm, land number: 152, land pitch: 0.65 mm, land diameter: 300 μm, length from a land end to a package end: 350 μm, substrate thickness: 310 μm, mold height: about 450 μm.

### Example 1

a) The adhesive layer γ was applied on one surface of the base material layer β so that a thickness thereof after dried was 30 μm, and it was dried at 130° C. for 3 minutes. Then, the release film γ was stuck on an exposed surface of the adhesive layer γ0 to prepare a sheet on which the base material layer β/the adhesive layer γ/the release film γ were laminated.

Next, the adhesive layer α was applied on a releasing-treated surface of the release film α so that a thickness thereof after dried was 10 μm, and it was dried at 90° C. for 2 minutes. A base material layer face of the sheet described above was stuck on an exposed surface of the adhesive layer immediately after dried to obtain a sheet material [A] for a spacer sheet having a layer structure: release film γ (38 μm)/adhesive layer γ (30 μm)/base material layer β (125 μm)/adhesive layer α (10 μm)/release film α (38 μm). The sheet material [A] assumed, as shown in FIG. 5, a three layer structure excluding the release films α and γ, and it had a thickness of 165 μm excluding those of the release films α and γ and a volume resistivity of 1×10¹⁷ Ω·cm.

b) Next, through holes for inserting connection terminals were provided on the sheet material [A] in an array corresponding to electrodes of a substrate by means of a carbon dioxide gas laser irradiating machine (Lavia 1000TW, manufactured by Sumitomo Heavy Industries, Ltd.). The above through holes had, as shown in FIG. 5, a cone shape [(through hole maximum diameter: 350 μm, release film α side), (through hole minimum diameter: 300 μm, release film γ side)]. A sheet having a through hole group of a three lines shown in FIG. 6 was obtained by providing the above through holes.
c) Then, a pattern of an outer periphery and a space part (outer periphery: 14×14 mm, space part (inner periphery): 11×11 mm) was provided by a punching work to obtain two sheets of a spacer sheet [A] shown in FIG. 7.
d) Separately, a flux was applied on electrodes formed on upper surfaces of substrates (hereinafter referred to as upper and lower substrates) in upper and lower BGA semiconductor packages by a screen printing method, and then lead-free solders (diameter: 260 μm) were set thereon. The packages were put in an IR reflow (maximum temperature: 260° C., manufactured by Senju Metal Industry Co., Ltd.) to form connection terminals (bumps) on the electrodes of the upper and lower substrates.
e) The release film γ of the spacer sheet [A] was peeled, and an adhesive layer γ side thereof was opposed to the substrate of the upper semiconductor package. The connection terminals of the electrodes in the spacer sheet [A] were inserted into the through holes and stuck (First Laminator UA-400III, manufactured by Taisei Laminator Co., Ltd., conditions: pressure 0.3 MPa, speed: 0.1 m/minute, temperature: 130° C.).

In the same manner, the connection terminals of the electrodes of the lower semiconductor package were inserted into the through holes in the other sheet of the spacer sheet [A] and stuck.

f) A flux was applied on the connection terminals formed in d) by a screen printing method.
g) The release film α of the spacer sheet stuck onto the upper and lower substrates in e) was peeled, and the connection terminals of the electrodes in the upper BGA semiconductor package and the connection terminals of the electrodes in the lower BGA semiconductor package were subjected to positioning to bring the connection terminals into contact. They were put in an IR reflow (maximum temperature: 260° C., manufactured by Senju Metal Industry Co., Ltd.) to fuse the opposed connection terminals of the upper and lower substrates, whereby the substrate of the upper BGA semiconductor package was connected with the substrate of the lower BGA semiconductor package. In this case, the opposed connection terminals were fused, and at the same time, the opposed adhesive layers α of the upper and lower spacer sheets stuck onto the upper and lower substrates were adhered with each other. Possibility of electrical connection and a distance between the upper and lower substrates in the complex type semiconductor device thus obtained were measured. The results thereof are shown in Table 1.

### Example 2

a) The adhesive layer β was applied on one surface of the base material layer α so that a thickness thereof after dried was 30 μm, and it was dried at 130° C. for 2 minutes. Then, the release film β was stuck on an exposed surface of the adhesive layer β to prepare a sheet on which the base material layer α/the adhesive layer β/the release film β were laminated.

Next, the adhesive layer δ was applied on a releasing-treated surface of the release film α so that a thickness thereof after dried was 60 μm, and it was dried at 90° C. for 2 minutes. A base material layer face of the sheet described above was stuck on an exposed surface of the adhesive layer immediately after dried to obtain a sheet material [B] for a spacer sheet having a layer structure: release film α (38 μm)/adhesive layer δ (60 μm)/base material layer α (75 μm)/adhesive layer β (30 μm)/release film β (38 μm). The sheet material [B] assumed, as shown in FIG. 5, a three layer structure excluding the release films α and β, and it had a thickness of 165 μm excluding those of the release films α and β and a volume resistivity of 1×10¹⁷ Ω·cm.

b) Next, through holes for inserting connection terminals were provided on the sheet material [B] in an array corresponding to electrodes of a substrate by means of a carbon dioxide gas laser irradiating machine (Lavia 1000TW, manufactured by Sumitomo Heavy Industries, Ltd.). The above through holes had, as shown in FIG. 5, a cone shape [(through hole maximum diameter: 350 μm, release film β side), (through hole minimum diameter: 300 μm, release film α side)]. A sheet having a through hole group of a three lines shown in FIG. 6 was obtained by providing the above through holes.
c) Then, a punching work (outer periphery: 14×14 mm, inner periphery: 8×8 mm) of a pattern was carried out by punching (perforating) to provide a space part 106, whereby two sheets of a spacer sheet [B] shown in FIG. 7 were obtained.
d) The electrodes of the upper and lower substrates and the corresponding through holes of the spacer sheet [B] after peeling the release film α at a substrate side were subjected to positioning to stick them (First Laminator UA-400III, manufactured by Taisei Laminator Co., Ltd., conditions: pressure 0.3 MPa, speed: 0.1 m/minute, temperature: 23° C.). Then, the sheet was put in a drying machine at 160° C. for one hour in order to cure the adhesive layer δ which was thermosetting.
e) Thereafter, each one of a lead-free solder (diameter 260 μm) was put in the respective through holes of the spacer sheet stuck on the upper and lower substrates, and then a flux was sprayed on an upper surface of the spacer sheet, whereby the flux was applied on the surfaces of the solder balls and the respective through holes.
f) Next, the upper and lower substrates were put respectively in an IR reflow (maximum temperature: 260° C., manufactured by Senju Metal Industry Co., Ltd.) to form connection terminals on the electrodes of the upper and lower substrates.
g) A flux was applied on the connection terminals prepared in f) by a screen printing method.
h) Next, the release film β at a side opposite to the substrate in the spacer sheet stuck onto the upper and lower substrates was peeled, and then the connection terminals of the electrodes in the upper BGA semiconductor package and the connection terminals of the electrodes in the lower BGA semiconductor package were subjected to positioning to bring the connection terminals into contact. They were put in an IR reflow (maximum temperature: 260° C., manufactured by Senju Metal Industry Co., Ltd.) to fuse the opposed connection terminals of the substrates in the upper BGA semiconductor package, whereby the substrate of the upper BGA semiconductor package was connected with the substrate of the lower BGA semiconductor package. In this case, the opposed connection terminals were fused, and at the same time, the opposed adhesive layers β of the upper and lower spacer sheets stuck onto the substrates of the upper and lower BGA semiconductor packages were adhered with each other. Possibility of electrical connection and a distance between the upper and lower substrates in the complex type semiconductor device thus obtained were measured. The results thereof are shown in Table 1.

### Example 3

a) The adhesive layer δ was applied on a releasing-treated surface of the release film α so that a thickness thereof after dried was 50 μm, and it was dried at 90° C. for 2 minutes. This allowed a film in which the adhesive layer δ was laminated on the release film a to be prepared.

Next, the adhesive layer δ was applied on one surface of another release film α so that a thickness thereof after dried was 50 μm, and it was dried at 90° C. for 2 minutes. Then, an adhesive layer surface of the sheet described above was stuck on an exposed surface of the adhesive layer immediately after dried to prepare a sheet on which the release film α/the adhesive layer δ (100 μm)/the release film α were laminated.

Further, the adhesive layer β was applied on a releasing-treated surface of the release film β so that a thickness thereof after dried was 65 μm, and it was dried at 130° C. for 3 minutes. Then, the adhesive layer δ of the sheet (release film α/adhesive layer δ (100 μm)/release film α) prepared above was stuck on the adhesive layer β immediately after dried while peeling one release film α of the sheet to obtain a sheet material [C] for a spacer sheet. The sheet material [C] assumed a four layer structure (two layer structure excluding the release films α and β) of the release film α (38 μm)/the adhesive layer δ (100 μm)/the adhesive layer β (65 μm)/the release film β (38 μm), and it had a thickness of 165 μm excluding those of the release films α and β and a volume resistivity of 8×10¹⁵ Ω·cm.

The same subsequent steps as in Example 2 were carried out to obtain two sheets of a spacer sheet [C], and further a complex type semiconductor device was prepared. Possibility of electrical connection and a distance between the upper and lower substrates in the complex type semiconductor device thus obtained were measured. The results thereof are shown in Table 1.

### Example 4

a) The adhesive layer γ was applied on a releasing-treated surface of the release film γ so that a thickness thereof after dried was 55 μm, and it was dried at 130° C. for 3 minutes. This allowed a film in which the adhesive layer γ was laminated on the release film γ to be prepared.

Next, the adhesive layer γ was applied on one surface of another release film γ so that a thickness thereof after dried was 55 μm, and it was dried at 130° C. for 3 minutes. Then, an adhesive layer surface of the sheet described above was stuck on an exposed surface of the adhesive layer immediately after dried to prepare a sheet on which the release film γ/the adhesive layer γ (110 μm)/the release film γ were laminated.

Further, the adhesive layer 3 was applied on a releasing-treated surface of the release film γ so that a thickness thereof after dried was 55 μm, and it was dried at 130° C. for 3 minutes. Next, the adhesive layer γ of the sheet (release film γ/adhesive layer γ (110 μm)/release film γ) prepared above was stuck on the adhesive layer γ immediately after dried while peeling one release film γ of the sheet to obtain a sheet material [D] for a spacer sheet. The sheet material [D] assumed, as shown in FIG. 3, a three layer structure (single layer structure excluding the release films γ) of the release film γ (38 μm)/the adhesive layer γ (165 μm)/the release film γ (38 μm), and it had a thickness of 165 μm excluding those of the release films γ and a volume resistivity of 1×10¹⁵ Ω·cm.

The same subsequent steps as in Example 1 were carried out to obtain two sheets of a spacer sheet [C], except that a through hole work was carried out by a drill method, and further a complex type semiconductor device was prepared. Possibility of electrical connection and a distance between the upper and lower substrates in the complex type semiconductor device thus obtained were measured. The results thereof are shown in Table 1.

### Comparative Example 1

The same steps as in Example 1 were carried out without using a spacer sheet. Accordingly, the procedure was carried out excluding the steps of a), b), c), e) and f) in Example 1. Possibility of electrical connection and a distance between the upper and lower substrates in the complex type semiconductor device thus obtained were measured. The results thereof are shown in Table 1.

### Comparative Example 2

The same steps as in Comparative Example 1 were carried out, except that a diameter of the solder ball was changed to 280 μm. Possibility of electrical connection and a distance between the upper and lower substrates in the complex type semiconductor device thus obtained were measured. The results thereof are shown in Table 1.

### Comparative Example 3

The same steps as in Comparative Example 1 were carried out, except that a diameter of the solder ball was changed to 300 μm. Possibility of electrical connection and a distance between the upper and lower substrates in the complex type semiconductor device thus obtained were measured. The results thereof are shown in Table 1.

TABLE 1

| | Possibility of | Distance between the upper |
|---|---|---|
| | electrical connection | and lower substrates (μm) |
| Example 1 | OK | 330 |
| Example 2 | OK | 328 |
| Example 3 | OK | 328 |
| Example 4 | OK | 330 |
| Comparative | No (short of height) | 300 (upper and lower |
| Example 1 | | semiconductor packages |
| | | were brought into contact) |
| Comparative | No (short of height) | 300 (upper and lower |
| Example 2 | | semiconductor packages |
| | | were brought into contact) |
| Comparative | No (short-circuited | 335 |
| Example 3 | with adjacent terminal) | |

As shown in Table 1, connection between the upper and lower substrates was possible in all of Examples 1 to 4, and electrical connection was confirmed without causing problems such as short circuit and the like.

Further, a distance between the substrates was secured without being brought into contact with the principal parts of the packages.

In Comparative Examples 1 and 2, the heights of the connection terminals run short, and the semiconductor packages mounted on the upper and lower substrates were brought into contact with each other. In addition thereto, a distance between the substrates run short, whereby a peripheral part of the substrates was bent. In Comparative Example 3, contact between the semiconductor packages was not caused, but short circuit between the adjacent connection terminals was brought about by an increase in a diameter of the connection terminals.

### INDUSTRIAL APPLICABILITY

The spacer sheet of the present invention and the production process for a complex type semiconductor device prepared by using the same make it possible to carry out stable electrical connection in POP type semiconductor packages and are suitably used for producing various complex type semiconductor devices. A complex type semiconductor device obtained by using the same has a high packaging density and is suitably used as a part for various computers, portable phones, various mobile devices and the like.

1. A complex type semiconductor device formed by laminating plural semiconductor packages, comprising
an upper semiconductor package which comprises a substrate for wiring and connecting provided with electrodes for conducting packages on a lower surface in the upper semiconductor package and a principal part of the upper semiconductor package disposed on an upper surface and/or a lower surface of the above substrate and which constitutes a relatively upper part,
a lower semiconductor package which comprises a substrate for wiring and connecting provided with electrodes for conducting packages on an upper surface in the lower semiconductor package and a principal part of the lower semiconductor package disposed on an upper surface and/or a lower surface of the above substrate and which constitutes a relatively lower part,
a spacer sheet which comprises a space part corresponding to the principal part of the upper semiconductor package and/or the principal part of the lower semiconductor package disposed between the adjacent upper and lower substrates and through holes disposed in a periphery of the above space part and allowing the electrodes oppositely disposed between the substrates to be communicated with each other and which is adhered onto the above substrates and inserted therebetween,
connection terminals which are provided in an inside of the through holes in the spacer sheet and which are used for conducting the substrates and
connection terminals for external connection which are formed on a lower surface of a substrate for wiring and connecting in a semiconductor package located in a lowermost part.

2. A semiconductor package which is used for a complex type semiconductor device formed by laminating plural semiconductor packages and which constitutes a relatively upper part of the complex type semiconductor device, comprising
a substrate for wiring and connecting in which electrodes for conducting packages are disposed on a lower surface,
a principal part of the semiconductor package disposed on an upper surface and/or a lower surface of the above substrate,
a spacer sheet which is adhered on a lower surface of the above substrate and which comprises a space part corresponding to a principal part of the above semiconductor package and/or a principal part of a semiconductor package disposed adjacent at a lower side of the above semiconductor package and through holes present in a periphery of the above space part and formed in positions corresponding to the electrodes and
connection terminals provided in an inside of the through holes in the spacer sheet.

3. A semiconductor package which is used for a complex type semiconductor device formed by laminating plural semiconductor packages and which constitutes a relatively lower part of the complex type semiconductor device, comprising
a substrate for wiring and connecting in which electrodes for conducting packages are disposed on an upper surface,
a principal part of the semiconductor package disposed on an upper surface and/or a lower surface of the above substrate,
a spacer sheet which is adhered on an upper surface of the above substrate and which comprises a space part corresponding to a principal part of the above semiconductor package and/or a principal part of a semiconductor package disposed adjacent at an upper side of the above semiconductor package and through holes present in a periphery of the above space part and formed in positions corresponding to the electrodes and
connection terminals provided in an inside of the through holes in the spacer sheet.

4. A spacer sheet for a complex type semiconductor device which is used by inserting between a substrate for wiring and connecting in an upper semiconductor package and a substrate for wiring and connecting in a lower semiconductor package in a complex type semiconductor device formed by laminating plural semiconductor packages, wherein:
it can be adhered to the substrate for wiring and connecting in the upper semiconductor package and the substrate for wiring and connecting in the lower semiconductor package; and it comprises
through holes which communicate electrodes disposed on mutually opposite surfaces of the substrate for wiring and connecting in the upper semiconductor package and the substrate for wiring and connecting in the lower semiconductor package and
a space part corresponding to a principal part of the upper semiconductor package disposed on a lower surface of the substrate for wiring and connecting in the upper semiconductor package and/or a principal part of the lower semiconductor package disposed on an upper surface of the substrate for wiring and connecting in the lower semiconductor package.

5. A set of spacer sheets for a complex type semiconductor device comprising a first spacer sheet which can be adhered to a substrate for wiring and connecting in a semiconductor package constituting an upper part of a complex type semiconductor device formed by laminating plural semiconductor packages and a second spacer sheet which can be adhered to a substrate for wiring and connecting in a semiconductor package constituting a lower part of the above complex type semiconductor device, wherein:
the first spacer sheet comprises through holes of an array corresponding to electrodes of the substrate for wiring and connecting in the above upper semiconductor package and a space part corresponding to a principal part of the upper semiconductor package and/or a principal part of the lower semiconductor package;
the second spacer sheet comprises through holes of an array corresponding to electrodes of the substrate for wiring and connecting in the above lower semiconductor package and a space part corresponding to a principal part of the upper semiconductor package and/or a principal part of the lower semiconductor package;
all of the through holes and the space part in the first spacer sheet and all of the through holes and the space part in the second spacer sheet assume plane symmetry; and
opposite surfaces of the first spacer sheet and the second spacer sheet are formed so that they can be adhered.

6. A set of the spacer sheets for a complex type semiconductor device according to claim 5, wherein the through holes of the first and/or second spacer sheet are cone-shaped, and they can be barrel-shaped by laminating.

7. A sheet material used for the spacer sheet for a complex type semiconductor device according to claim 4.

8. A production process for a complex type semiconductor device formed by laminating plural semiconductor packages, comprising:
a step of preparing an upper semiconductor package which comprises a substrate for wiring and connecting in the upper semiconductor package provided with electrodes for conducting packages on a lower surface and a principal part of the upper semiconductor package disposed on an upper surface and/or a lower surface of the above substrate and which constitutes a relatively upper part,
a step of preparing a lower semiconductor package which comprises a substrate for wiring and connecting in the lower semiconductor package provided with electrodes for conducting packages on an upper surface and a principal part of the lower semiconductor package disposed on an upper surface and/or a lower surface of the above substrate and which constitutes a relatively lower part,
a step in which connection terminals for conducting the above substrates are formed respectively on the electrodes of the substrates in the upper and lower semiconductor packages,
a step of preparing a spacer sheet comprising a space part corresponding to a principal part of the upper semiconductor package and/or a principal part of the lower semiconductor package which are disposed between the upper and lower substrates and through holes disposed in a periphery of the above space part which allow the electrodes oppositely disposed between the substrates to be communicated with each other and
a step in which the respective corresponding positions of the principal parts of the semiconductor packages and the space parts and the corresponding positions of the electrodes and the through holes are fitted to adhere the spacer sheet onto a lower surface of the substrate in the upper semiconductor package and adhere it onto an upper surface of the substrate in the lower semiconductor package.

9. A production process for a complex type semiconductor device formed by laminating plural semiconductor packages, comprising:
a step of preparing an upper semiconductor package comprising a substrate for wiring and connecting in the upper semiconductor package provided with electrodes for conducting packages on a lower surface and a principal part of the upper semiconductor package disposed on an upper surface and/or a lower surface of the above substrate and constituting a relatively upper part,
forming connection terminals on the electrodes, and
adhering a first spacer sheet onto a lower surface of the substrate in the upper semiconductor package,
the first spacer sheet comprising a space part corresponding to a principal part of the upper semiconductor package and/or a principal part of a lower semiconductor package disposed between the upper and lower substrates and through holes disposed in a periphery of the above space part, allowing the electrodes oppositely disposed between the substrates to be communicated with each other and being prepared to fit the positions of the principal part of the semiconductor package and the space part, and the corresponding positions of the electrodes and the through holes; and
a step of preparing a lower semiconductor package comprising a substrate for wiring and connecting in the lower semiconductor package provided with electrodes for conducting packages on an upper surface and a principal part of the lower semiconductor package disposed on an upper surface and/or a lower surface of the above substrate and constituting a relatively lower part,
forming connection terminals on the electrodes, and
adhering a second spacer sheet onto a lower surface of the substrate in the lower semiconductor package,
the second spacer sheet comprising a space part corresponding to a principal part of the upper semiconductor package and/or a principal part of the lower semiconductor package disposed between the upper and lower substrates and through holes disposed in a periphery of the above space part, allowing the electrodes oppositely disposed between the substrates to be communicated with each other and being prepared to fit the positions of the principal part of the semiconductor package and the space part, and the corresponding positions of the electrodes and the through holes;
wherein the first spacer sheet and the second spacer sheet are fitted in the corresponding positions of the through holes and oppositely faced to adhere them to each other, and the connection terminals brought into contact are fused and integrated.
